(19) United States
(12) Patent Application Publication
(10) Pub. No.: US 2007/0092998 A1
(43) Pub. Date: Apr. 26, 2007

(54) Semiconductor heat-transfer method

(76) Inventors: Ruey-Feng Tai, Changhua City (TW); Yun Tai, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/253,662

(22) Filed: Oct. 20, 2005

(51) Int. Cl. H01L 21/00

(52) U.S. Cl. 438/110; 438/117; 438/121

(57) ABSTRACT

A semiconductor heat-transfer method includes the steps of (a) treating a high conductivity metal substrate through an electrolytic oxidation process to have an oxidized insulation layer be covered on the surface of the high conductivity metal substrate, (b) covering a metal conducting layer on the oxidized insulation layer at selected locations, and (c) installing an electronic device in the high conductivity metal substrate and bonding lead wires to the electronic device and the metal conducting layer for enabling produced heat to be transferred to the metal substrate for quick dissipation during working of the electronic device.

### BACKGROUND OF THE INVENTION

1. Field of the Invention

The present invention relates to the fabrication of semiconductor products and more specifically, to a semiconductor heat-transfer method.

2. Description of the Related Art

A semiconductor heat-transfer material is known by: spray-coating or printing an insulative coating material on the surface of a well-washed metal substrate, and then baking the insulative coating material to a dry status to form an insulative layer on the metal substrate, and then making a conducting layer on the insulative layer. The insulative coating material is prepared by mixing a rock flour with a resin and a solvent. This method still has numerous drawbacks as outlined hereinafter:
(1) The insulative layer is not joined to the metal substrate at a zero gap status, and the gap between the insulative layer and the metal substrate imparts a barrier to the transfer of heat energy.
(2) In order to obtain a wick structure in the insulative layer, the insulative layer must be made having a certain thickness, however the thick insulative layer imparts a barrier to the transfer of heat energy.
(3) Because the heat conductivity of the non-metal material is poor, the heat energy produced by the electronic device installed in the conducting layer cannot be quickly transferred to the metal substrate for quick dissipation.

### SUMMARY OF THE INVENTION

The present invention has been accomplished under the circumstances in view. The semiconductor heat-transfer method of the present invention includes the steps of (a) treating a high conductivity metal substrate through an electrolytic oxidation process to have an oxidized insulation layer be covered on the surface of the high conductivity metal substrate, (b) covering a metal conducting layer on the oxidized insulation layer at selected locations, and (c) installing an electronic device in the high conductivity metal substrate and bonding lead wires to the electronic device and the metal conducting layer for enabling produced heat to be transferred to the metal substrate for quick dissipation during working of the electronic device. The invention has the following advantages:
(1) The zero-gap connection between the oxidized insulative layer improves heat-transfer efficiency.
(2) The heat produced during the operation of the electronic device can efficiently evenly be transferred to the metal substrate for quick dissipation.
(3) The oxidized insulative layer has a thin thickness to facilitate transfer of heat energy.
(4) The oxidized insulative layer has heat and voltage resisting characteristics.
(5) The semiconductor device can be freely processed to fit the contour of the electronic device to be installed.

### BRIEF DESCRIPTION OF THE DRAWINGS

FIG. 1 is a sectional view of a heat-transfer semiconductor device for LED type lighting fixture according to the present invention.

FIG. 2 is an elevational view of the heat-transfer semiconductor device shown in FIG. 1.

FIG. 3 is a flow chart of the present invention.

FIG. 4 is a sectional view of an alternate form of the heat-transfer semiconductor device according to the present invention.

FIG. 5 is an exploded view of still another alternate form of the heat-transfer semiconductor device according to the present invention.

FIG. 6 is an exploded view of still another alternate form of the heat-transfer semiconductor device according to the present invention.

FIG. 7 is an exploded view of still another alternate form of the heat-transfer semiconductor device according to the present invention.

### DETAILED DESCRIPTION OF THE PREFERRED EMBODIMENT

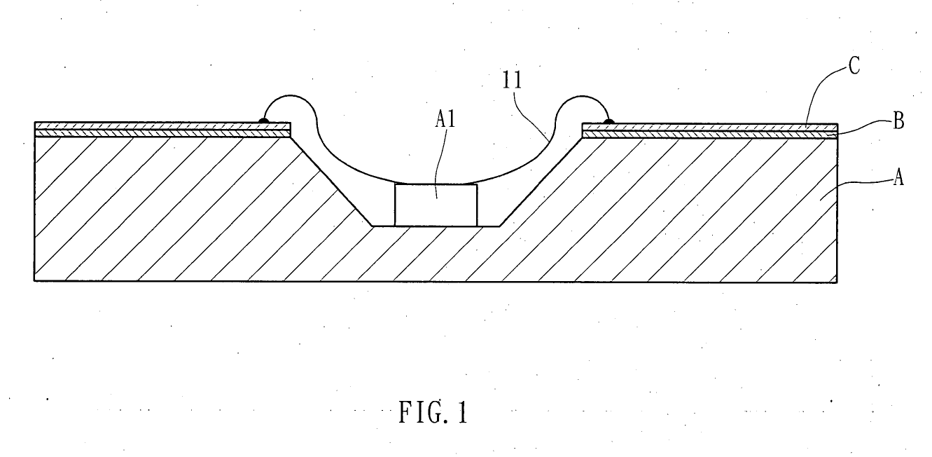

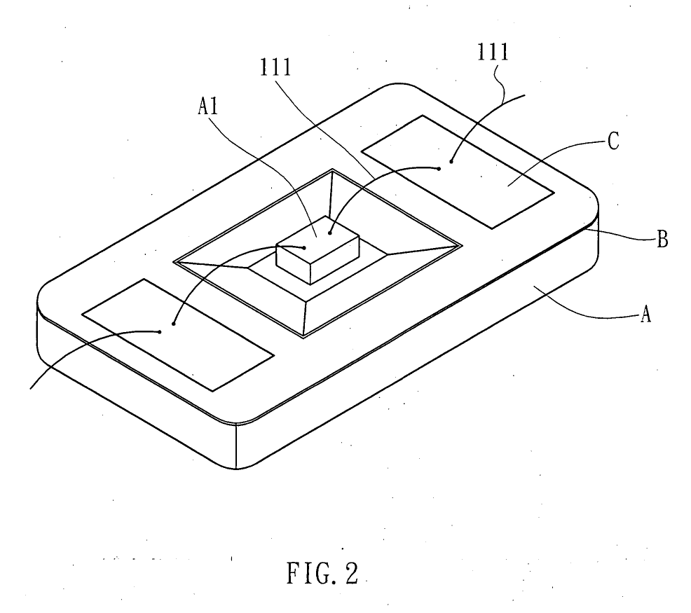

Referring to FIGS. 1 and 2, a high conductivity metal substrate A is treated through an electrolytic oxidation process to have an oxidized insulation layer B be covered on the surface thereof. The oxidized insulation layer B has high temperature and high voltage resisting characteristics. Thereafter, a metal conducting layer C is coated on the oxidized insulation layer B at selected locations by electroplating or semiconductor photolithography technology. Lead wires 111 are bonded to the metal conducting layer C and electronic device(s) A1 at the high conductivity metal substrate A. During the operation of the electronic device(s) A1, produced heat is quickly transferred to the high conductivity metal substrate A for quick dissipation.

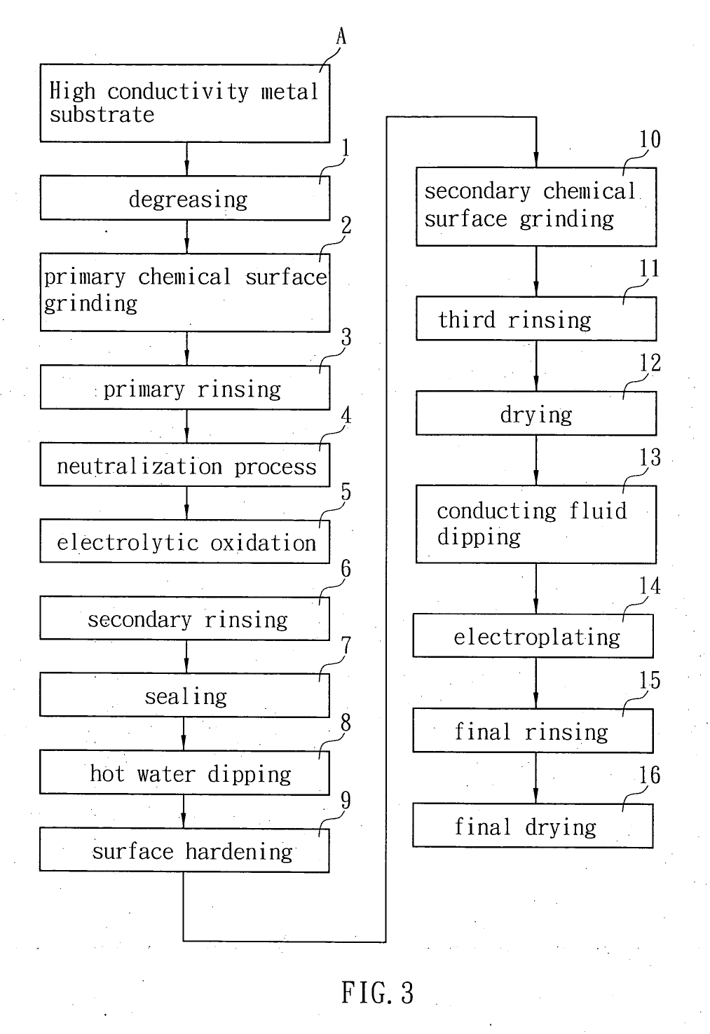

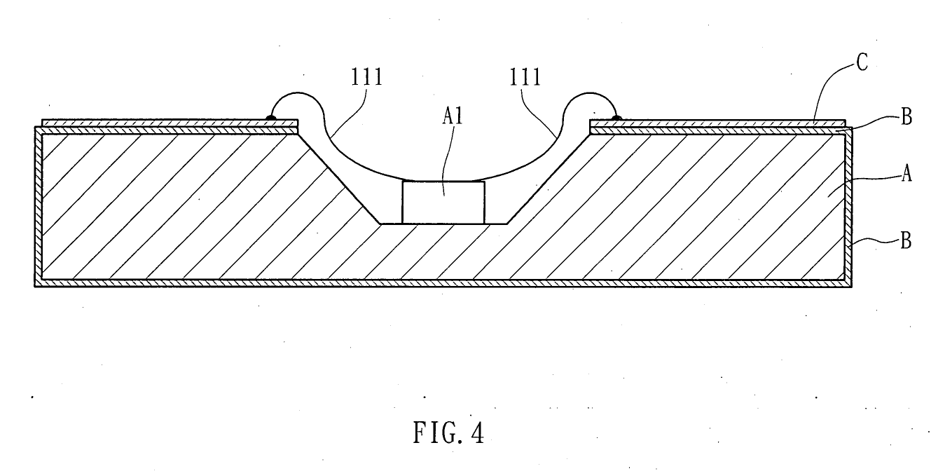

Referring to FIGS. 3 and 4, the aforesaid electrolytic oxidation process is employed to the high conductivity metal substrate A after the high conductivity metal substrate A has been well cleaned with running water. The invention includes the steps of (1) degreasing, (2) primary chemical surface grinding, (3) primary rinsing, (4) neutralization process, (5) electrolytic oxidation, (6) secondary rinsing, (7) sealing, (8) hot water dipping, (9) surface hardening, (10) secondary chemical surface grinding, (11) third rinsing, and (12) drying. If electroplating process is employed to form the metal conducting layer C on the oxidized insulation layer B at the high conductivity metal substrate A, the method of the present invention further includes the steps of (13) conducting fluid dipping, (14) electroplating, (15) final rinsing, and (16) final drying.

The aforesaid metal conducting layer C may be directly printed on the oxidized insulation layer B at the high conductivity metal substrate A at selected locations.

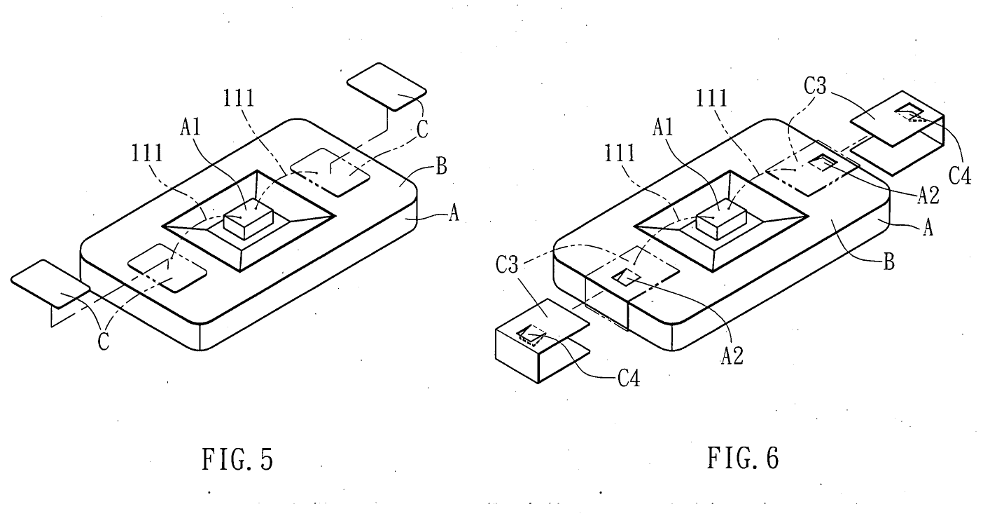

Referring to FIG. 5, the metal conducting layer C may be comprised of a plurality of metal conducting sheet members directly bonded to the oxidized insulation layer B at the high conductivity metal substrate A at selected locations.

Referring to FIG. 6, the aforesaid metal conducting layer C may be comprised of a plurality of metal clamping plates C3 respectively clamped on the oxidized insulation layer B at the high conductivity metal substrate A at selected locations. The metal clamping plates C3 each have a hooked portion C4 hooked in a respective hook hole A2 in the oxidized insulation layer B at the high conductivity metal substrate A.

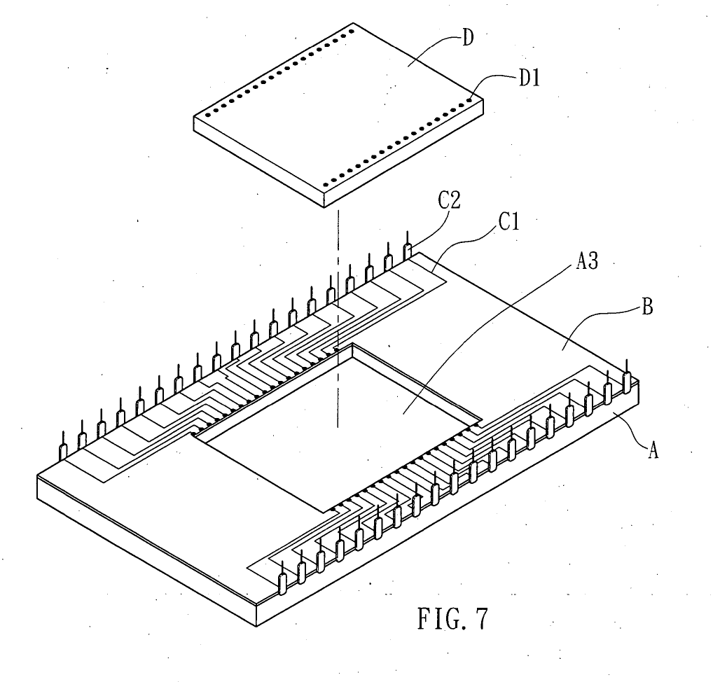

FIG. 7 shows an application example of the present invention in an integrated circuit. As illustrated, the high conductivity metal substrate A has an oxidized insulation layer B covered thereon and a conducting layer, which is comprised of a plurality of conducting lines C1 respectively covered on the oxidized insulation layer B at selected locations and respectively electrically connected to respective pins C2 at the border of the high conductivity metal substrate A, and an electronic device D is mounted in a recessed hole A3 that is formed on the high conductivity metal substrate A and cut through the oxidized insulation layer B. The electronic device D has contacts D1 respectively electrically connected to respective pins C2 at the high conductivity metal substrate A through the conducting lines C1. During the operation of the electronic device D, produced heat is transferred from the electronic device D through the conducting lines C1 and the pins C2 to the high conductivity metal substrate A for quick dissipation.

Although particular embodiments of the invention have been described in detail for purposes of illustration, various modifications and enhancements may be made without departing from the spirit and scope of the invention. Accordingly, the invention is not to be limited except as by the appended claims.

1. A semiconductor heat-transfer method comprising the steps of:
(a) preparing a high conductivity metal substrate and then treating said high conductivity metal substrate through an electrolytic oxidation process to have an oxidized insulation layer be covered on the surface of said high conductivity metal substrate;
(b) covering a metal conducting layer on said oxidized insulation layer at selected locations; and
(c) installing an electronic device in said high conductivity metal substrate and bonding lead wires to said electronic device and said metal conducting layer.

2. The semiconductor heat-transfer method as claimed in claim 1, wherein said electrolytic oxidation process includes the steps of: (1) degreasing, (2) primary chemical surface grinding, (3) primary rinsing, (4) neutralization process, (5) electrolytic oxidation, (6)secondary rinsing, (7) sealing, (8) hot water dipping, (9) surface hardening, (10) secondary chemical surface grinding, (11) third rinsing, and (12) drying.

3. The semiconductor heat-transfer method as claim in claim 1, wherein said metal conducting layer is formed on said oxidized insulation layer at selected locations by an electroplating process, which includes the steps of (a) conducting fluid dipping, (b) electroplating, (c) rinsing, and (d) drying.

4. The semiconductor heat-transfer method as claimed in claim 1, wherein said metal conducting layer is comprised of a plurality of conducting lines.

5. The semiconductor heat-transfer method as claimed in claim 1, wherein said metal conducting layer is comprised of a plurality of conducting sheet members respectively bonded to said oxidized insulation layer at selected locations.

6. The semiconductor heat-transfer method as claimed in claim 1, wherein said metal conducting layer is comprised of a plurality of metal clamps respectively clamped on said oxidized insulation layer at said high conductivity metal substrate at selected locations, said metal clamping plates C3 each having a hooked portion hooked in a respective hook hole in said oxidized insulation layer at said high conductivity metal substrate.

7. The semiconductor heat-transfer method as claimed in claim 1, wherein said metal conducting layer is directly printed on said oxidized insulation layer at said high conductivity metal substrate at selected locations.

8. The semiconductor heat-transfer method as claimed in claim 1, wherein said oxidized insulation layer is covered on the whole surface of said high conductivity metal substrate.
